(19) United States
(12) Patent Application Publication
(10) Pub. No.: US 2013/0120721 A1
(43) Pub. Date: May 16, 2013

(54) LIGHT-EMITTING DEVICE, METHOD FOR MANUFACTURING THE SAME, AND PROJECTOR

(71) Applicant: Seiko Epson Corporation, Tokyo (JP)

(72) Inventors: Hiroyasu KASEYA, Fujimi (JP); Mitsuru SATO, Suwa (JP)

(73) Assignee: SEIKO EPSON CORPORATION, Tokyo (JP)

(21) Appl. No.: 13/676,451

(22) Filed: Nov. 14, 2012

(30) Foreign Application Priority Data
Nov. 16, 2011 (JP) 2011-250377

(51) Int. Cl. H01L 33/48; G03B 21/20; H01L 33/00

(52) U.S. Cl. CPC H01L 33/48; H01L 33/005; G03B 21/2033
USPC 353/122; 257/79; 438/22

(57) ABSTRACT

A light-emitting device includes: a semiconductor light-emitting element; a substrate supporting the semiconductor light-emitting element; and a silicone elastomer layer located between the semiconductor light-emitting element and the substrate, wherein the semiconductor light-emitting element and the silicone elastomer layer are bonded together.

### BACKGROUND

1. Technical Field

The present invention relates to a light-emitting device, a method for manufacturing the same, and a projector.

2. Related Art

In recent years, the development of semiconductor light-emitting elements has been vigorously carried out. As specific semiconductor light-emitting elements, a semiconductor laser (Laser Diode), a super luminescent diode (hereinafter also referred to as “SLD”), an LED (Light-Emitting Diode), and the like have been known.

In a light-emitting device including a semiconductor light-emitting element, the semiconductor light-emitting element is generally mounted on a support substrate such as a copper base. In such a light-emitting device, stress is sometimes generated in the semiconductor light-emitting element due to a difference in the coefficient of thermal expansion between the semiconductor light-emitting element and the support substrate because of, for example, heat generation at the time of driving the semiconductor light-emitting element, a change in ambient temperature caused by a change in environment in which the device is put, or the like. When the stress is generated in the semiconductor light-emitting element, the device cannot offer desired performance or the reliability of the device is lowered in some cases.

For such problems, JP-A-2007-73549, for example, discloses a light-emitting device in which a semiconductor light-emitting element is mounted on a support substrate via a submount so that stress generated in the semiconductor light-emitting element due to a difference in the coefficient of thermal expansion between the semiconductor light-emitting element and the support substrate can be reduced.

However, in the light-emitting device disclosed in JP-A-2007-73549, the semiconductor light-emitting element is bonded with solder such as AuSn. Since solder such as AuSn is hard (the modulus of elasticity is large), the deformation of the semiconductor light-emitting element isnot allowed when the semiconductor light-emitting element attempts to deform because of heat generation at the time of driving the semiconductor light-emitting element, a change in ambient temperature caused by a change in environment in which the device is put, or the like, and therefore, stress is sometimes generated in the semiconductor light-emitting element.

### SUMMARY

An advantage of some aspects of the invention is to provide a light-emitting device which can reduce stress generated in a semiconductor light-emitting element due to a member bonded to the semiconductor light-emitting element and a method for manufacturing the light-emitting device. Another advantage of some aspects of the invention is to provide a projector including the light-emitting device.

An aspect of the invention is directed to a light-emitting device including: a semiconductor light-emitting element; a substrate supporting the semiconductor light-emitting element; and a silicone elastomer layer located between the semiconductor light-emitting element and the substrate, wherein the semiconductor light-emitting element and the silicone elastomer layer are bonded together.

According to the light-emitting device, since the silicone elastomer layer is soft (the modulus of elasticity is small) compared to solder, the deformation of the semiconductor light-emitting element is not prevented when the semiconductor light-emitting element attempts to deform because of heat generation at the time of driving the semiconductor light-emitting element, a change in ambient temperature caused by a change in environment in which the device is put, or the like, and therefore, it is possible to suppress the generation of stress in the semiconductor light-emitting element. Accordingly, according to the light-emitting device, it is possible to reduce the stress generated in the semiconductor light-emitting element due to a member bonded to the semiconductor light-emitting element.

In the light-emitting device according to the aspect of the invention, the semiconductor light-emitting element and the silicone elastomer layer may be bonded together by activated bonding.

According to the light-emitting device, it is possible, in the manufacturing process, to reduce thermal damage or physical damage applied to the semiconductor light-emitting element. In the light-emitting device according to the aspect of the invention, the semiconductor light-emitting element may be mounted on the substrate in a junction-down state.

According to the light-emitting device, a heat dissipation property can be enhanced.

In the light-emitting device according to the aspect of the invention, the semiconductor light-emitting element may be an edge-emitting semiconductor light-emitting element.

According to the light-emitting device, it is possible to prevent a precursor of the silicone elastomer layer from adhering to a light-exiting portion of the semiconductor light-emitting element in, for example, bonding of the semiconductor light-emitting element with the silicone elastomer layer. Accordingly, even when an edge-emitting semiconductor light-emitting element is used as the semiconductor light-emitting element, it is possible to prevent the occurrence of problems, such as a reduction in the intensity of exiting light or the occurrence of abnormality in the shape of exiting light, due to the adherence of the precursor to the light-exiting portion.

In the light-emitting device according to the aspect of the invention, the light-emitting device may further include a silicon substrate located between the silicone elastomer layer and the substrate.

According to the light-emitting device, it is possible to reduce stress generated in the semiconductor light-emitting element due to a difference in the coefficient of thermal expansion between the semiconductor light-emitting element and the substrate.

In the light-emitting device according to the aspect of the invention, the semiconductor light-emitting element may have an electrode disposed on a surface of the semiconductor light-emitting element, a wiring may be disposed on a surface of the substrate, the surface facing the surface of the semiconductor light-emitting element, and the electrode and the wiring may be electrically connected through a connecting portion configured to include a conductive material and a resin material.

According to the light-emitting device, the electrode and the wiring can be electrically connected while reducing stress generated in the semiconductor light-emitting element.

In the light-emitting device according to the aspect of the invention, the semiconductor light-emitting element may have an electrode disposed on a surface of the semiconductor light-emitting element, a wiring may be disposed on a surface of the silicon substrate, the surface facing the surface of the semiconductor light-emitting element, and the electrode and the wiring may be electrically connected through a connecting portion configured to include a conductive material and a resin material.

According to the light-emitting device, the electrode and the wiring can be electrically connected while reducing stress generated in the semiconductor light-emitting element. Another aspect of the invention is directed to a method for manufacturing a light-emitting device, including: forming a silicone elastomer layer above a substrate; subjecting a surface of the silicone elastomer layer to activation treatment; and placing a semiconductor light-emitting element on the silicone elastomer layer.

According to the method for manufacturing the light-emitting device, it is possible to obtain the light-emitting device which can reduce stress generated in the semiconductor light-emitting element due to a member bonded to the semiconductor light-emitting element. Further, since the semiconductor light-emitting element and the silicone elastomer layer can be bonded together by activated bonding, it is possible, in the manufacturing process, to reduce thermal damage and physical damage applied to the semiconductor light-emitting element.

It is noted that, in the descriptions concerning the invention, the term “above” may be used, for example, in a manner as “a specific element (hereafter referred to as “A”) is formed “above” another specific element (hereafter referred to as “B”).” In the descriptions concerning the invention, in the case of such an example, the term “above” is used, while assuming that it includes a case in which A is formed directly on B, and a case in which A is formed above B through another element.

The method for manufacturing the light-emitting device according to the aspect of the invention may further include: patterning, after the forming of the silicone elastomer layer, the silicone elastomer layer so as to expose a wiring disposed between the substrate and the silicone elastomer layer; and arranging conductive paste on the exposed wiring, wherein in the placing of the semiconductor light-emitting element on the silicone elastomer layer, the semiconductor light-emitting element may be placed such that an electrode of the semiconductor light-emitting element and the wiring are connected via the conductive paste.

According to the method for manufacturing the light-emitting device, the electrode and the wiring can be electrically connected while reducing stress generated in the semiconductor light-emitting element.

In the method for manufacturing the light-emitting device according to the aspect of the invention, the forming of the silicone elastomer layer may include applying a precursor of the silicone elastomer layer above the substrate and curing the precursor by heat treatment to form the silicone elastomer layer.

According to the method for manufacturing the light-emitting device, the semiconductor light-emitting element can be placed on the silicone elastomer layer in a state where the silicone elastomer layer is cured. Accordingly, in placing of the semiconductor light-emitting element on the silicone elastomer layer, it is possible to prevent the precursor of the silicone elastomer layer from adhering to a light-exiting portion of the semiconductor light-emitting element.

Still another aspect of the invention is directed to a method for manufacturing a light-emitting device, including: forming a silicone elastomer layer above a silicon substrate; subjecting a surface of the silicone elastomer layer to activation treatment; placing a semiconductor light-emitting element on the silicone elastomer layer; and bonding the silicon substrate to a substrate.

According to the method for manufacturing the light-emitting device, it is possible to obtain the light-emitting device which can reduce stress generated in the semiconductor light-emitting element due to a member bonded to the semiconductor light-emitting element. Further, since the semiconductor light-emitting element and the silicone elastomer layer can be bonded together by activated bonding, it is possible, in the manufacturing process, to reduce thermal damage and physical damage applied to the semiconductor light-emitting element.

The method for manufacturing the light-emitting device according to the aspect of the invention may further include: patterning, after the forming of the silicone elastomer layer, the silicone elastomer layer so as to expose a wiring disposed between the silicon substrate and the silicone elastomer layer; and arranging conductive paste on the exposed wiring, wherein in the placing of the semiconductor light-emitting element on the silicone elastomer layer, the semiconductor light-emitting element may be placed such that an electrode of the semiconductor light-emitting element and the wiring are connected via the conductive paste.

According to the method for manufacturing the light-emitting device, the electrode and the wiring can be electrically connected while reducing stress generated in the semiconductor light-emitting element.

In the method for manufacturing the light-emitting device according to the aspect of the invention, the forming of the silicone elastomer layer may include applying a precursor of the silicone elastomer layer above the silicon substrate and curing the precursor by heat treatment to form the silicone elastomer layer.

According to the method for manufacturing the light-emitting device, the semiconductor light-emitting element can be placed on the silicone elastomer layer in a state where the silicone elastomer layer is cured. Accordingly, in placing of the semiconductor light-emitting element on the silicone elastomer layer, it is possible to prevent the precursor of the silicone elastomer layer from adhering to a light-exiting portion of the semiconductor light-emitting element.

Yet another aspect of the invention is directed to a projector including: the light-emitting device according to the aspect of the invention; a light-modulating device modulating light emitted from the light-emitting device according to image information; and a projection device projecting an image formed by the light-modulating device.

According to the projector, since the light-emitting device according to the aspect of the invention is included, it is possible to reduce stress generated in the semiconductor light-emitting element due to a member bonded to the semiconductor light-emitting element.

### BRIEF DESCRIPTION OF THE DRAWINGS

The invention will be described with reference to the accompanying drawings, wherein like numbers reference like elements.

FIG. 1 is a cross-sectional view schematically showing a light-emitting device according to a first embodiment.

FIG. 2 is a plan view schematically showing a semiconductor light-emitting element.

FIG. 3 is a cross-sectional view schematically showing the semiconductor light-emitting element.

FIG. 4 is a cross-sectional view schematically showing the manufacturing process of the light-emitting device according to the first embodiment.

FIG. 5 is a cross-sectional view schematically showing the manufacturing process of the light-emitting device according to the first embodiment.

FIG. 6 is a cross-sectional view schematically showing the manufacturing process of the light-emitting device according to the first embodiment.

FIG. 7 is a cross-sectional view schematically showing the manufacturing process of the light-emitting device according to the first embodiment.

FIG. 8 is a cross-sectional view schematically showing the manufacturing process of the light-emitting device according to the first embodiment.

FIG. 9 is a cross-sectional view schematically showing the manufacturing process of the light-emitting device according to the first embodiment.

FIG. 10 is a cross-sectional view schematically showing a light-emitting device according to a first modified example of the first embodiment.

FIG. 11 is a cross-sectional view schematically showing the manufacturing process of the light-emitting device according to the first modified example of the first embodiment.

FIG. 12 is a cross-sectional view schematically showing the manufacturing process of the light-emitting device according to the first modified example of the first embodiment.

FIG. 13 is a cross-sectional view schematically showing the manufacturing process of the light-emitting device according to the first modified example of the first embodiment.

FIG. 14 is a cross-sectional view schematically showing the manufacturing process of the light-emitting device according to the first modified example of the first embodiment.

FIG. 15 is a cross-sectional view schematically showing the manufacturing process of the light-emitting device according to the first modified example of the first embodiment.

FIG. 16 is a cross-sectional view schematically showing the manufacturing process of the light-emitting device according to the first modified example of the first embodiment.

FIG. 17 is a cross-sectional view schematically showing a second modified example of the manufacturing process of the light-emitting device according to the first embodiment.

FIG. 18 is a cross-sectional view schematically showing the second modified example of the manufacturing process of the light-emitting device according to the first embodiment.

FIG. 19 is a cross-sectional view schematically showing the second modified example of the manufacturing process of the light-emitting device according to the first embodiment.

FIG. 20 is a cross-sectional view schematically showing a light-emitting device according to a second embodiment.

FIG. 21 is a cross-sectional view schematically showing the manufacturing process of the light-emitting device according to the second embodiment.

FIG. 22 is a cross-sectional view schematically showing the manufacturing process of the light-emitting device according to the second embodiment.

FIG. 23 is a cross-sectional view schematically showing a light-emitting device according to a modified example of the second embodiment.

FIG. 24 is a cross-sectional view schematically showing the manufacturing process of the light-emitting device according to the modified example of the second embodiment.

FIG. 25 is a cross-sectional view schematically showing the manufacturing process of the light-emitting device according to the modified example of the second embodiment.

FIG. 26 is a cross-sectional view schematically showing the manufacturing process of the light-emitting device according to the modified example of the second embodiment.

FIG. 27 schematically shows a projector according to a third embodiment.

### DESCRIPTION OF EXEMPLARY EMBODIMENTS

Hereinafter, preferred embodiments of the invention will be described with reference to the drawings.

### 1. First Embodiment

### 1.1. Configuration of Light-Emitting Device

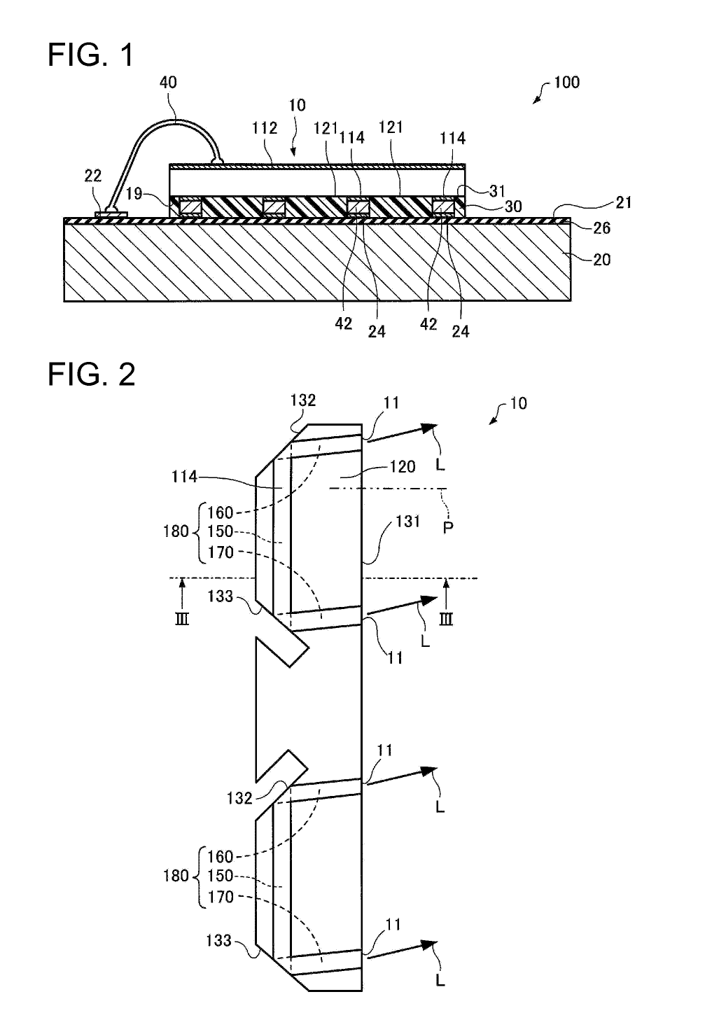

First, the configuration of a light-emitting device according to a first embodiment will be described with reference to the drawings. FIG. 1 is a cross-sectional view schematically showing the light-emitting device 100 according to the embodiment. In FIG. 1, a semiconductor light-emitting element 10 is illustrated in a simplified manner for convenience sake. As shown in FIG. 1, the light-emitting device 100 includes the semiconductor light-emitting element 10, a substrate (hereinafter also referred to as “support substrate”) 20, and a silicone elastomer layer 30.

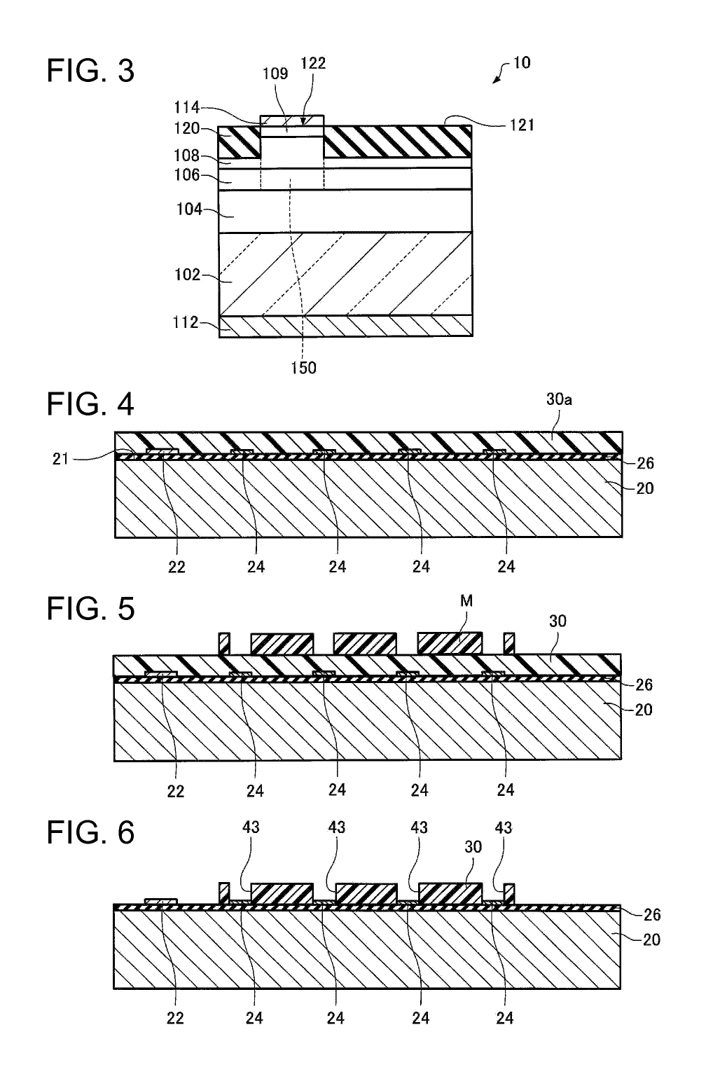

As the semiconductor light-emitting element 10, a semiconductor laser, an SLD (super luminescent diode), and an LED, for example, can be used. Especially an SLD can reduce speckle noise compared to a semiconductor laser, and achieve higher output compared to an LED. Therefore, an SLD is preferable when, for example, the light-emitting device 100 is used for a light source of a projector or the like. FIG. 2 is a plan view schematically showing the semiconductor light-emitting element 10. FIG. 3 is a cross-sectional view schematically showing the semiconductor light-emitting element 10, taken along line III-III of FIG. 2. In the following, the description will be made on the case where the semiconductor light-emitting element 10 is an edge-emitting SLD.

As shown in FIGS. 2 and 3, the semiconductor light-emitting element 10 can have a substrate 102, a first cladding layer 104, an active layer 106, a second cladding layer 108, a contact layer 109, a first electrode 112, second electrodes 114, and an insulating portion 120.

As the substrate 102, a GaAs substrate of a first conductivity type (for example, n-type) or the like, for example, is used. The first cladding layer 104 is formed on the substrate 102. As the first cladding layer 104, an n-type InGaAlP layer or the like, for example, is used.

The active layer 106 is formed on the first cladding layer 104. The active layer 106 has, for example, a multi-quantum well (MQW) structure in which three quantum well structures each having an InGaP well layer and an InGaAlP barrier layer are stacked. In the example shown in FIG. 2, the active layer 106 has a first side surface 131 where light-exiting portions 11 are formed, and second side surfaces 132 and third side surfaces 133 which are inclined to the first side surface 131. Portions of the active layer 106 constitute first gain regions 150, second gain regions 160, and third gain regions 170. The gain regions 150, 160, and 170 can generate light. This light can be guided within the gain regions 150, 160, and 170 while experiencing gains.

As shown in FIG. 2, the first gain region 150 is disposed from the second side surface 132 to the third side surface 133. In the illustrated example, the first gain region 150 is disposed parallel to the first side surface 131.

The second gain region 160 is disposed from the second side surface 132 to the first side surface 131. The second gain region 160 overlaps the first gain region 150 on the second side surface 132.

The third gain region 170 is disposed from the third side surface 133 to the first side surface 131. The third gain region 170 overlaps the first gain region 150 on the third side surface 133.

In the light generated in the gain regions 150, 160, and 170, the reflectance of the first side surface 131 is lower than those of the second side surface 132 and the third side surface 133. With this configuration, a connecting portion between the second gain region 160 and the first side surface 131, and a connecting portion between the third gain region 170 and the first side surface 131 can each serve as the light-exiting portion 11. Moreover, the side surfaces 132 and 133 can each serve as a reflecting surface.

The gain regions 160 and 170 are connected to the first side surface 131 while being inclined to a normal P of the first side surface 131. With this configuration, it is possible to prevent the direct multiple reflection of light generated in the gain regions 150, 160, and 170 between an edge face on the first side surface 131 of the second gain region 160 and an edge face on the first side surface 131 of the third gain region 170. As a result, since a resonator cannot be directly configured, laser oscillation of the light generated in the gain regions 150, 160, and 170 can be suppressed or prevented. The gain regions 150, 160, and 170 can constitute a gain region group 180. In the semiconductor light-emitting element 10, a plurality of gain region groups 180 are disposed. Although, in the illustrated example, two gain region groups 180 are disposed, the number of gain region groups is not particularly limited.

The second cladding layer 108 is formed on the active layer 106. As the second cladding layer 108, an InGaAlP layer of a second conductivity type (for example, p-type) or the like, for example, is used.

For example, the p-type second cladding layer 108, the active layer 106 not doped with an impurity, and the n-type first cladding layer 104 constitute a pin diode. Each of the first cladding layer 104 and the second cladding layer 108 is a layer whose forbidden band width is larger and whose refractive index is smaller than those of the active layer 106. The active layer 106 has functions of generating light and guiding the light while amplifying the light. The first cladding layer 104 and the second cladding layer 108 have a function of interposing the active layer 106 therebetween to confine injected carriers (electrons and holes) and light (a function of suppressing light leakage).

When the forward bias voltage of the pin diode is applied (a current is injected) between the first electrode 112 and the second electrode 114, the semiconductor light-emitting element 10 generates the gain regions 150, 160, and 170 in the active layer 106, and the recombination of electrons and holes occurs in the gain regions 150, 160, and 170. This recombination causes light emission. With this generated light as a starting point, stimulated emission occurs successively, so that the intensity of light is amplified within the gain regions 150, 160, and 170. Then, the light whose intensity is amplified is emitted from the light-exiting portion 11 as light L. That is, in the illustrated example, the semiconductor light-emitting element 10 is an edge-emitting semiconductor light-emitting element.

The contact layer 109 and a portion of the second cladding layer 108 can constitute a columnar portion 122. The planar shape of the columnar portion 122 is the same as that of the gain regions 150, 160, and 170. That is, it can be said that the planar shape of an upper surface of the contact layer 109 is the same as that of the gain regions 150, 160, and 170. For example, a current path between the electrodes 112 and 114 is determined by the planar shape of the columnar portion 122, and as a result, the planar shape of the gain regions 150, 160, and 170 is determined.

The insulating portion 120 is disposed lateral to the columnar portion 122 on the second cladding layer 108. As the insulating portion 120, a SiN layer, a SiO₂ layer, a SiON layer, an Al₂O₃ layer, or a polyimide layer, for example, is used.

When the material described above is used as the insulating portion 120, a current between the electrodes 112 and 114 can avoid the insulating portion 120 to flow through the columnar portion 122 interposed between the insulating portions 120. The insulating portion 120 can have a refractive index smaller than that of the active layer 106. In this case, the effective refractive index of a vertical section of a portion where the insulating portion 120 is formed is smaller than that of a portion where the insulating portion 120 is not formed, that is, the effective refractive index of a vertical section of a portion where the columnar portion 122 is formed. With this configuration, light can be efficiently confined within the gain regions 150, 160, and 170 in a planar direction. The first electrode 112 is formed on an entire lower surface of the substrate 102. As the first electrode 112, one obtained by stacking a Cr layer, an AuGe layer, a Ni layer, and an Au layer from the substrate 102 side in this order, for example, is used.

The second electrode 114 is formed on the contact layer 109. The planar shape of the second electrode 114 is, for example, the same as that of the gain regions 150, 160, and 170. As the second electrode 114, one obtained by stacking a Cr layer, an AuZn layer, and an Au layer from the contact layer 109 side in this order, for example, is used.

The semiconductor light-emitting element 10 is formed by semiconductor fabrication techniques such as a photolithographic technique and an etching technique.

As shown in FIG. 1, the semiconductor light-emitting element 10 is mounted on the support substrate 20 in a junction-down state. That is, the semiconductor light-emitting element 10 is mounted such that the active layer 106 is located closer to the support substrate 20 side than the substrate 102 of the semiconductor light-emitting element 10. In the example of FIG. 1, the semiconductor light-emitting element 10 is mounted with the second electrode 114 side being directed to the support substrate 20 (turned upside down from the example of FIG. 3). Therefore, a first surface 19 as a surface of the semiconductor light-emitting element 10 faces a second surface (upper surface) 21 of the support substrate 20. The first surface 19 of the semiconductor light-emitting element 10 is a surface on which the second electrodes 114 are formed and which is composed of the upper surface of the contact layer 109 and an upper surface 121 of the insulating portion 120 shown in FIG. 3. In the illustrated example, since the semiconductor light-emitting element 10 is an edge-emitting semiconductor light-emitting element, the light-exiting portion 11 of the semiconductor light-emitting element 10 is disposed on a surface perpendicular to the upper surface 21 of the support substrate 20. Therefore, the exiting light L which is emitted from the light-exiting portion 11 proceeds in a direction along the upper surface 21 of the support substrate 20.

The support substrate 20 supports the semiconductor light-emitting element 10. In the illustrated example, the support substrate 20 supports the semiconductor light-emitting element 10 via the silicone elastomer layer 30. As the support substrate 20, a plate-like member (rectangular parallelepiped-shaped member), for example, can be used. The support substrate 20 is formed of, for example, Cu, Al, Mo, W, Si, C, Be, or Au, or a compound (for example, AlN, BeO, or the like) or an alloy (for example, CuMo or the like) of them. Moreover, the support substrate 20 can also be composed of a combination of these examples, for example, a multi-layered structure of a copper (Cu) layer and a molybdenum (Mo) layer, or the like. The support substrate 20 can, for example, dissipate heat generated in the semiconductor light-emitting element 10.

On the upper surface 21 of the support substrate 20, a first wiring 22 and second wirings 24 are disposed. In the illustrated example, the first wiring 22 and the second wirings 24 are disposed on the upper surface 21 of the support substrate 20 via an insulating layer 26. The insulating layer 26 is a layer for electrically insulating the wirings 22 and 24 from each other. The insulating layer 26 is, for example, a silicon oxide layer or a silicon nitride layer. The first wiring 22 and the second wirings 24 are, for example, wirings for connecting the semiconductor light-emitting element 10 with a driving portion (not shown) for driving the semiconductor light-emitting element 10.

The first wiring 22 is electrically connected with the first electrode 112 of the semiconductor light-emitting element 10 through, for example, a wiring wire 40. Although not shown in the drawing, the first wiring 22 may be electrically connected with the first electrode 112 through a connecting portion 42, similarly to the second wiring 24 which will be described later, when the semiconductor light-emitting element 10 has a single-sided electrode structure in which the electrodes 112 and 114 are formed on the same surface side with respect to the substrate 102.

The second wiring 24 is electrically connected with the second electrode 114 of the semiconductor light-emitting element 10 through the connecting portion 42. The second wiring 24 is disposed at a position facing the second electrode 114. The planar shape of the second wiring 24 is, for example, the same as that of the second electrode 114. In plan view, the second electrode 114 may be formed on the inner side of the outer edge of the second wiring 24. In the illustrated example, a plurality of second wirings 24 are disposed in one-to-one correspondence with the plurality of second electrodes 114. The connecting portion 42 is disposed between the second wiring 24 and the second electrode 114. The connecting portion 42 is disposed, in plan view, in an overlapped region of the second electrode 114 with the second wiring 24. The connecting portion 42 may be disposed in a portion of the overlapped region of the second electrode 114 with the second wiring 24, or may be disposed in the entire overlapped region. The connecting portion 42 can conduct the heat generated in the semiconductor light-emitting element 10 to the support substrate 20. The connecting portion 42 is disposed in a hole penetrating through the silicone elastomer layer 30 in its thickness direction. The planar shape of the hole is, for example, the same as that of the second electrode 114. A plurality of connecting portions 42 are disposed in one-to-one correspondence with the plurality of second electrodes 114.

The connecting portion 42 is configured to include, for example, a conductive material and a resin material. Examples of the conductive material include, for example, silver (Ag), copper (Cu), and carbon (C). Examples of the resin material include, for example, a silicone resin, an epoxy resin, a phenol resin, and an acrylic resin. A silicone resin is compatible with the silicone elastomer layer 30, and therefore is preferable as the resin material. The connecting portion 42 is formed by curing conductive paste including a conductive material and a resin material. Since the connecting portion 42 includes a resin material, the connecting portion 42 is soft (the modulus of elasticity is low) compared to, for example, the case of being formed only of a conductive material such as metal. Accordingly, by connecting the second wiring 24 and the second electrode 114 with the connecting portion 42, the second electrode 114 and the wiring 24 can be electrically connected while reducing stress generated in the semiconductor light-emitting element 10 compared to, for example, the case where a connecting portion is formed only of a conductive material such as metal.

The silicone elastomer layer 30 is located between the semiconductor light-emitting element 10 and the support substrate 20. Here, the case where the silicone elastomer layer 30 is located between the semiconductor light-emitting element 10 and the support substrate 20 can mean a state where at least a portion of the silicone elastomer layer 30 is located between the semiconductor light-emitting element 10 and the support substrate 20. That is, it is defined that the case where the silicone elastomer layer 30 is located between the semiconductor light-emitting element 10 and the support substrate 20 includes also the case where a portion of the silicone elastomer layer 30 is located between the semiconductor light-emitting element 10 and the support substrate 20 and the other portion of the silicone elastomer layer 30 is not located between the semiconductor light-emitting element 10 and the support substrate 20. In the illustrated example, an entirety of the silicone elastomer layer 30 is located between the semiconductor light-emitting element 10 and the support substrate 20.

The silicone elastomer layer 30 and the semiconductor light-emitting element 10 are bonded together by activated bonding. More specifically, an upper surface 31 of the silicone elastomer layer 30 and the upper surface 121 of the insulating portion 120 of the semiconductor light-emitting element 10 are bonded together by activated bonding. Here, the activated bonding is a technique of bonding by, for example, irradiating a bonding surface (in this case, the upper surface 31 of the silicone elastomer layer 30) with plasma, ultraviolet light, or the like to form a dangling bond (dangling bond in an atom) on the bonding surface and bringing this activated surface into contact with an object surface (in this case, the upper surface 121 of the insulating portion 120). Accordingly, the upper surface 31 of the silicone elastomer layer 30 and the upper surface 121 of the insulating portion 120 of the semiconductor light-emitting element 10 are directly bonded together without another member (adhesive or the like). An entirety of the upper surface 121 of the insulating portion 120 may be bonded with the upper surface 31 of the silicone elastomer layer 30, or a portion of the upper surface 121 of the insulating portion 120 may be bonded with the upper surface 31 of the silicone elastomer layer 30.

The silicone elastomer layer 30 is a layer configured to include, for example, a silicone elastomer. For example, the silicone elastomer layer 30 may be composed only of a silicone elastomer. The silicone elastomer is a silicone which has a —Si—O—Si— bond in a molecule and is cured rubbery by the addition of a curing catalyst, such as a peroxide or a platinum compound, or cured by partial crystallization. Specifically, the material of the silicone elastomer layer 30 is, for example, polydimethylsiloxane, polysilsesquioxane, or the like. As the silicone elastomer layer 30, a silicone manufactured by, for example, Momentive Performance Materials Japan LLC, part number TSE3221S can be used. The silicone elastomer layer 30 is soft (the modulus of elasticity is small) compared to solder such as AuSn. Therefore, in the light-emitting device 100, since the semiconductor light-emitting element 10 and the silicone elastomer layer 30 are bonded together, the deformation of the semiconductor light-emitting element 10 is not prevented when the semiconductor light-emitting element 10 attempts to deform, and therefore, the generation of stress in the semiconductor light-emitting element 10 can be suppressed compared to the case where the semiconductor light-emitting element 10 and solder are bonded together. The film thickness of the silicone elastomer layer 30 is, for example, about 3 to 10 μm. By making the silicone elastomer layer 30 thin in this manner, heat generated in the semiconductor light-emitting element 10 can be easily conducted to the support substrate 20.

The light-emitting device 100 according to the embodiment has, for example, the following features.

The light-emitting device 100 has the silicone elastomer layer 30 located between the semiconductor light-emitting element 10 and the support substrate 20, and the semiconductor light-emitting element 10 is bonded with the silicone elastomer layer 30. The silicone elastomer layer 30 is soft compared to, for example, solder such as AuSn. Therefore, the deformation of the semiconductor light-emitting element 10 is not prevented when the semiconductor light-emitting element 10 attempts to deform because of heat generation at the time of driving the semiconductor light-emitting element 10, a change in ambient temperature caused by a change in environment in which the light-emitting device 100 is placed, or the like, and therefore, the generation of stress in the semiconductor light-emitting element 10 can be suppressed compared to the case where the semiconductor light-emitting element 10 and solder are bonded together. Accordingly, according to the light-emitting device 100, it is possible to reduce stress generated in the semiconductor light-emitting element due to a member bonded to the semiconductor light-emitting element. Therefore, when a change in temperature is caused by heat generation at the time of driving the semiconductor light-emitting element, a change in ambient temperature caused by a change in environment in which the device is placed, or the like, the device does not fail to offer desired performance or the reliability of the device is not reduced for example, so that the device can have high reliability.

Moreover, since a submount is no more necessary in the light-emitting device 100, it is possible to reduce the cost, for example.

In the light-emitting device 100, the semiconductor light-emitting element 10 and the silicone elastomer layer 30 are bonded together by activated bonding. With this configuration, the semiconductor light-emitting element 10 and the silicone elastomer layer 30 can be bonded together at a room temperature without applying heat. Moreover, the semiconductor light-emitting element 10 and the silicone elastomer layer 30 can be bonded together with a low load. Accordingly, it is possible, in the manufacturing process, to reduce the thermal damage and physical damage applied to the semiconductor light-emitting element. For example, when a semiconductor light-emitting element is bonded to a submount with solder such as AuSn, heat at 300° C. or more is necessary for the bonding. Therefore, the semiconductor light-emitting element is sometimes damaged by this heat.

In the light-emitting device 100, the semiconductor light-emitting element 10 is mounted on the support substrate 20 in a junction-down state. With this configuration, since the active layer 106 as a heat-generating source can be brought close to the support substrate 20, the heat dissipation property can be enhanced.

In the light-emitting device 100, the semiconductor light-emitting element 10 is an edge-emitting semiconductor light-emitting element. In the light-emitting device 100, since the semiconductor light-emitting element 10 and the silicone elastomer layer 30 are bonded together by activated bonding, the silicone elastomer layer 30 can be bonded to the semiconductor light-emitting element 10 in a state where the silicone elastomer layer 30 is cured. Accordingly, in bonding of the semiconductor light-emitting element 10 with the silicone elastomer layer 30, it is possible to prevent a foreign substance such as a precursor of the silicone elastomer layer from adhering to the light-exiting portion 11 of the semiconductor light-emitting element 10. Accordingly, in the light-emitting device 100, even when an edge-emitting semiconductor light-emitting element is used as the semiconductor light-emitting element 10, it is possible, for example, to prevent the occurrence of problems, such as a reduction in the intensity of the exiting light L or the occurrence of abnormality in the shape of the exiting light L due to a foreign substance.

In the light-emitting device 100, the second electrode 114 of the semiconductor light-emitting element 10 and the wiring 24 disposed on the support substrate 20 are connected through the connecting portion 42 configured to include a conductive material and a resin material. Since the connecting portion 42 includes a resin material, the connecting portion 42 is soft (the modulus of elasticity is small) compared to, for example, the case where a wiring is composed only of a conductive material such as metal. Therefore, compared to the case where a wiring is composed only of a conductive material such as metal, the second electrode 114 and the wiring 24 can be electrically connected while reducing the stress generated in the semiconductor light-emitting element 10.

### 1.2. Method for Manufacturing Light-Emitting Device

Next, a method for manufacturing the light-emitting device 100 according to the first embodiment will be described with reference to the drawings. FIGS. 4 to 9 are cross-sectional views schematically showing the manufacturing process of the light-emitting device 100 according to the embodiment. In FIG. 9, the semiconductor light-emitting element 10 is illustrated in a simplified manner for convenience sake.

As shown in FIG. 4, the insulating layer 26 and the wirings 22 and 24 are formed on the upper surface 21 of the support substrate 20. The insulating layer 26 is formed by, for example, a sputtering method, a CVD method, or the like. The first wiring 22 and the second wirings 24 are formed by, for example, depositing a conductive layer (not shown) and then patterning the conductive layer using a lithographic technique, an etching technique, and the like. The support substrate 20 on which the insulating layer 26 and the wirings 22 and 24 are formed previously may be used.

Next, above the support substrate 20 (in the illustrated example, on the insulating layer 26 and on the wirings 22 and 24), a precursor 30a of the silicone elastomer layer 30 is applied. The precursor 30a is a liquid serving as a raw material for forming the silicone elastomer layer 30, and includes a material constituting the silicone elastomer layer 30. The application of the precursor 30a can be performed by, for example, a spin-coating method. This makes it possible to uniformly apply the precursor 30a on the insulating layer 26 and on the wirings 22 and 24. Moreover, by the use of a spin-coating method, the film thickness of the silicone elastomer layer 30 can be easily controlled. Accordingly, the silicone elastomer layer 30 can be made thin, for example. As shown in FIG. 5, the precursor 30a is cured by heat treatment. For example, the precursor 30a is cured by putting the support substrate 20 having the precursor 30a applied thereon in a bake furnace and applying heat at about from 150° C. to 180° C. Next, a mask M is formed on the silicone elastomer layer 30. The mask M is formed by applying a resist on the silicone elastomer layer 30, curing the resist, and then patterning through exposure and a development process.

As shown in FIG. 6, the silicone elastomer layer 30 is etched using the mask M as a mask. This makes it possible to pattern the silicone elastomer layer 30 into a desired shape. The silicone elastomer layer 30 is patterned so as to, for example, expose the first wiring 22 and the second wirings 24. In the illustrated example, holes 43 are formed in the silicone elastomer layer 30 by patterning, and the second wiring 24 is exposed through the hole 43. The etching of the silicone elastomer layer 30 is performed by, for example, dry etching. Next, the mask M is removed.

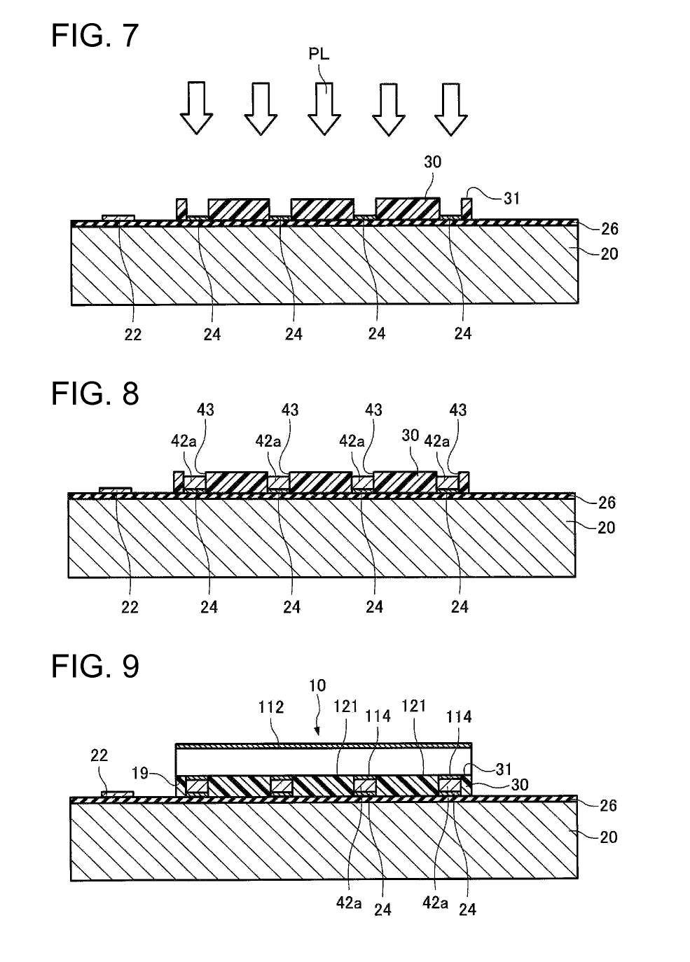

As shown in FIG. 7, the surface (the upper surface 31) of the silicone elastomer layer 30 is subjected to activation treatment. Specifically, the activation treatment can be performed by subjecting the surface of the silicone elastomer layer 30 to, for example, plasma treatment at an atmospheric pressure. In the example shown in FIG. 7, plasma treatment is performed by irradiating the surface of the silicone elastomer layer 30 with plasma PL. Moreover, the activation treatment may be performed by irradiating the surface of the silicone elastomer layer 30 with ultraviolet light. Here, the activation treatment means to create a state where a dangling bond of a surface atom is exposed by removing an oxide film, deposits, or the like of a bonding surface (surface of the silicone elastomer layer).

As shown in FIG. 8, conductive paste 42a is arranged on the second wirings 24. Specifically, the conductive paste 42a is arranged on the second wirings 24 by applying the conductive paste 42a in the holes 43. Moreover, the conductive paste 42a may be arranged on the second wirings 24 by, for example, transferring conductive paste which is previously patterned into a desired shape onto the second wirings 24. The conductive paste 42a is configured to include, for example, a conductive material and a resin material. Examples of the conductive material include, for example, silver (Ag), copper (Cu), and carbon (C). Examples of the resin material include, for example, a silicone resin, an epoxy resin, a phenol resin, and an acrylic resin.

As shown in FIG. 9, the semiconductor light-emitting element 10 is placed on the silicone elastomer layer 30. Specifically, the semiconductor light-emitting element 10 is placed such that the second electrode 114 of the semiconductor light-emitting element 10 and the second wiring 24 are connected via the conductive paste 42a. That is, the semiconductor light-emitting element 10 is flip-chip mounted in a junction-down state where the second electrode 114 is directed to the support substrate 20 side. The placement of the semiconductor light-emitting element 10 is performed using, for example, a flip chip bonder or the like.

By placing the semiconductor light-emitting element 10 on the silicone elastomer layer 30, the silicone elastomer layer 30 and the semiconductor light-emitting element 10 are bonded together by activated bonding. More specifically, the upper surface 31 of the silicone elastomer layer 30 and the upper surface 121 of the insulating portion 120 of the semiconductor light-emitting element 10 are bonded together by activated bonding. In addition to the upper surface 31 of the silicone elastomer layer 30, the upper surface 121 of the insulating portion 120 of the semiconductor light-emitting element 10 may be subjected to activation treatment. This makes it possible to further increase the bonding strength between the silicone elastomer layer 30 and the semiconductor light-emitting element 10.

Moreover, after placing the semiconductor light-emitting element 10 on the silicone elastomer layer 30, a load (bonding load) may be applied to the semiconductor light-emitting element 10. That is, the semiconductor light-emitting element 10 may be pressed against the silicone elastomer layer 30. Further, after placing the semiconductor light-emitting element 10 on the silicone elastomer layer 30, heat at about from 150° C. to 180° C. may be applied. This makes it possible to further increase the bonding strength between the silicone elastomer layer 30 and the semiconductor light-emitting element 10.

As shown in FIG. 1, the conductive paste 42a is cured by heat treatment to form the connecting portion 42. Next, the first wiring 22 and the first electrode 112 of the semiconductor light-emitting element 10 are connected through the wiring wire 40. The process is performed by, for example, wire bonding or the like.

Through the processes described above, the light-emitting device 100 can be manufactured.

The method for manufacturing the light-emitting device 100 according to the embodiment has, for example, the following features.

The method for manufacturing the light-emitting device 100 has the process of subjecting the surface of the silicone elastomer layer 30 to activation treatment and the process of placing the semiconductor light-emitting element 10 on the silicone elastomer layer 30. That is, according to the method for manufacturing the light-emitting device 100, the semiconductor light-emitting element 10 and the silicone elastomer layer 30 can be bonded together by activated bonding. With this configuration, the semiconductor light-emitting element 10 and the silicone elastomer layer 30 can be bonded together at a room temperature without applying heat. Further, the semiconductor light-emitting element 10 and the silicone elastomer layer 30 can be bonded together with a low load. Accordingly, it is possible, in the manufacturing process, to reduce damage applied to the semiconductor light-emitting element.

According to the method for manufacturing the light-emitting device 100, in the process of placing the semiconductor light-emitting element 10 on the silicone elastomer layer 30, the semiconductor light-emitting element 10 is placed such that the second electrode 114 of the semiconductor light-emitting element 10 and the second wiring 24 are connected via the conductive paste 42a. That is, the second electrode 114 of the semiconductor light-emitting element 10 and the second wiring 24 are connected through the connecting portion 42 including a conductive material and a resin material. With this configuration, the second electrode 114 and the second wiring 24 can be electrically connected while reducing stress generated in the semiconductor light-emitting element 10. According to the method for manufacturing the light-emitting device 100, the silicone elastomer layer 30 is formed by applying the precursor 30a of the silicone elastomer layer 30 above the support substrate 20 and curing the precursor 30a by heat treatment. Accordingly, since the semiconductor light-emitting element 10 can be placed on the cured silicone elastomer layer 30, it is possible to prevent the precursor 30a of the silicone elastomer layer from adhering to the light-exiting portion 11 of the semiconductor light-emitting element 10 in bonding of the semiconductor light-emitting element 10 with the silicone elastomer layer 30.

### 1.3. Modified Examples

### 1.3.1. First Modified Example

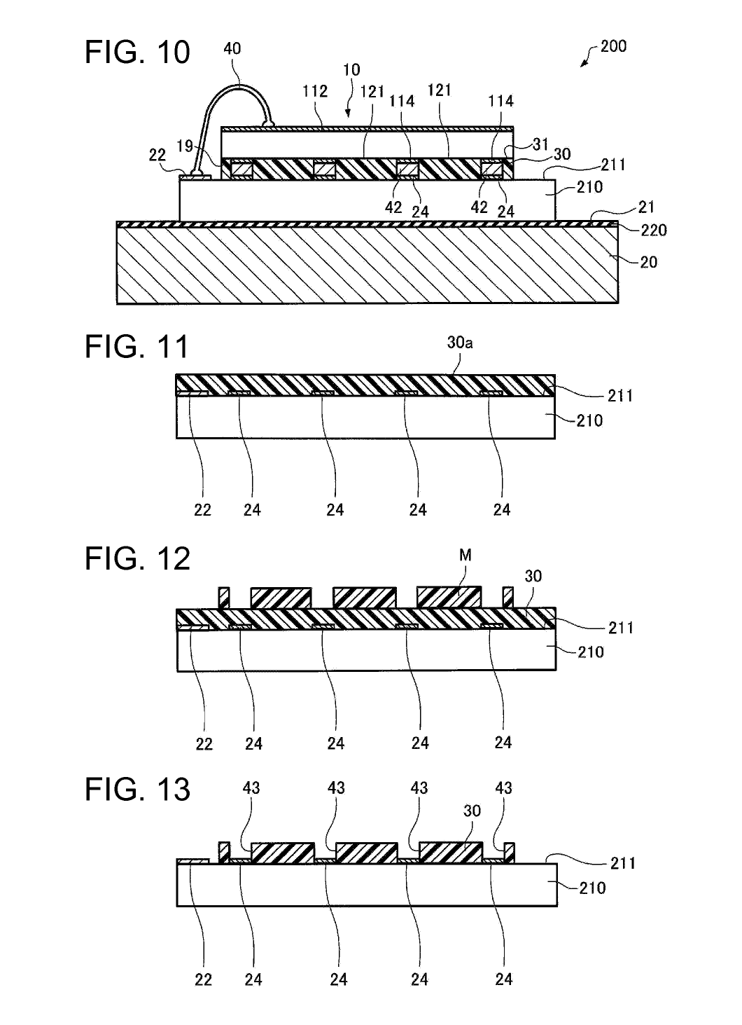

Next, a modified example of the light-emitting device according to the first embodiment will be described with reference to the drawing. FIG. 10 is a cross-sectional view schematically showing a light-emitting device 200 according to a first modified example of the first embodiment. In FIG. 10, the semiconductor light-emitting element 10 is illustrated in a simplified manner for convenience sake. Hereinafter, in the light-emitting device 200, members having functions similar to those of the constituent members of the light-emitting device 100 are denoted by the same reference and numeral signs, and the detailed description thereof is omitted.

As shown in FIG. 10, the light-emitting device 200 is configured to include, addition to the constituent members of the light-emitting device 100, a silicon substrate 210 located between the silicone elastomer layer 30 and the support substrate 20. That is, in the light-emitting device 200, the silicon substrate 210, the silicone elastomer layer 30, and the semiconductor light-emitting element 10 are arranged in this order above the support substrate 20.

In the light-emitting device 200, the first wiring 22 and the second wirings 24 are formed on the silicon substrate 210 (an upper surface 211 of the silicon substrate 210). The first wiring 22 may be disposed on the support substrate 20. The first wiring 22 is electrically connected with the first electrode 112 of the semiconductor light-emitting element 10 through, for example, the wiring wire 40. The second wiring 24 is electrically connected with the second electrode 114 of the semiconductor light-emitting element 10 through the connecting portion 42.

In the illustrated example, the silicone elastomer layer 30 and the silicon substrate 210 are located between the semiconductor light-emitting element 10 and the support substrate 20. Here, it is defined that the case where the silicone elastomer layer 30 is located between the semiconductor light-emitting element 10 and the support substrate 20 includes, not only the case where only the silicone elastomer layer 30 is located between the semiconductor light-emitting element 10 and the support substrate 20, but also the case where the silicone elastomer layer 30 and another member (in this case, the silicon substrate 210) are located between the semiconductor light-emitting element 10 and the support substrate 20.

The silicone elastomer layer 30 and the semiconductor light-emitting element 10 are bonded together by activated bonding. In the illustrated example, the silicone elastomer layer 30 is interposed between the upper surface 211 of the silicon substrate 210 and the first surface 19 as the surface of the semiconductor light-emitting element 10. The upper surface 211 of the silicon substrate 210 and the first surface 19 of the semiconductor light-emitting element 10 face each other via the silicone elastomer layer 30.

The silicon substrate 210 is bonded to the support substrate 20. The silicon substrate 210 and the support substrate 20 are bonded together with, for example, a bonding member 220 such as silver paste or heat-dissipating silicone. A difference between the thermal expansion coefficient (for example, linear expansion coefficient) of the silicon substrate 210 and the coefficient of thermal expansion of the semiconductor light-emitting element 10 is small compared to a difference between the thermal expansion coefficient of the support substrate 20 and the coefficient of thermal expansion of the semiconductor light-emitting element 10.

The light-emitting device 200 has, for example, the following features.

The light-emitting device 200 can have the silicon substrate 210 located between the silicone elastomer layer 30 and the support substrate 20. As described above, the difference between the thermal expansion coefficient of the silicon substrate 210 and the coefficient of thermal expansion of the semiconductor light-emitting element 10 is small compared to the difference between the thermal expansion coefficient of the support substrate 20 and the coefficient of thermal expansion of the semiconductor light-emitting element 10. Accordingly, according to the light-emitting device 200, it is possible to reduce stress generated in the semiconductor light-emitting element 10 due to the difference in the coefficient of thermal expansion between the semiconductor light-emitting element 10 and the support substrate 20. Next, a method for manufacturing the light-emitting device 200 will be described with reference to the drawings. FIGS. 11 to 16 are cross-sectional views schematically showing the manufacturing process of the light-emitting device 200. In FIG. 16, the semiconductor light-emitting element 10 is illustrated in a simplified manner for convenience sake. As shown in FIG. 11, the first wiring 22 and the second wirings 24 are formed on the upper surface 211 of the silicon substrate 210.

Next, the precursor 30a of the silicone elastomer layer 30 is applied on the silicon substrate 210 and on the wirings 22 and 24. The application of the precursor 30a can be performed by, for example, a spin-coating method.

As shown in FIG. 12, the precursor 30a is cured by heat treatment. For example, the precursor 30a is cured by putting the support substrate 20 having the precursor 30a applied thereon in a bake furnace and applying heat at about from 150° C. to 180° C. Next, the mask M is formed on the silicone elastomer layer 30. The mask M is formed by applying a resist on the silicone elastomer layer 30, curing the resist, and then patterning through exposure and a development process.

As shown in FIG. 13, the silicone elastomer layer 30 is etched using the mask M as a mask. The silicone elastomer layer 30 is patterned so as to, for example, expose the first wiring 22 and the second wirings 24. In the illustrated example, the holes 43 are formed in the silicone elastomer layer 30 by patterning, and the second wiring 24 is exposed through the hole 43. Next, the mask M is removed.

When the silicon substrate 210 is a wafer, the wafer may be cut into small pieces by dicing or the like after patterning the silicone elastomer layer 30.

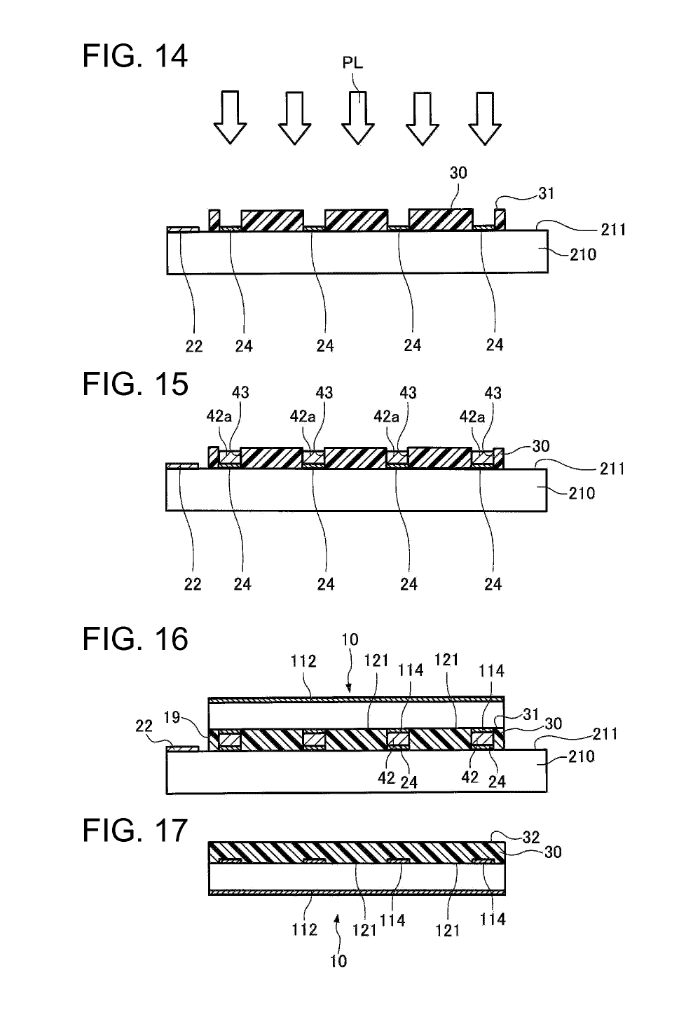

As shown in FIG. 14, the surface (the upper surface 31) of the silicone elastomer layer 30 is subjected to activation treatment by the irradiation of the plasma PL.

As shown in FIG. 15, the conductive paste 42a is arranged on the second wirings 24. Specifically, the conductive paste 42a is arranged on the second wirings 24 by applying the conductive paste 42a in the holes 43.

As shown in FIG. 16, the semiconductor light-emitting element 10 is placed on the silicone elastomer layer 30. Specifically, the semiconductor light-emitting element 10 is placed such that the second electrode 114 of the semiconductor light-emitting element 10 and the second wiring 24 are connected via the conductive paste 42a. That is, the semiconductor light-emitting element 10 is flip-chip mounted in a junction-down state where the second electrode 114 is directed to the silicon substrate 210 side.

By placing the semiconductor light-emitting element 10 on the silicone elastomer layer 30, the upper surface 31 of the silicone elastomer layer 30 and the upper surface 121 of the insulating portion 120 of the semiconductor light-emitting element 10 are bonded together by activated bonding.

As shown in FIG. 10, the conductive paste 42a is cured by heat treatment to form the connecting portion 42. Next, the first wiring 22 and the first electrode 112 of the semiconductor light-emitting element 10 are connected through the wiring wire 40.

Next, the silicon substrate 210 is bonded with the support substrate 20. The silicon substrate 210 and the support substrate 20 can be bonded together using, for example, the bonding member 220 such as silver paste or heat-dissipating silicone.

Through the processes described above, the light-emitting device 200 can be manufactured.

According to the method for manufacturing the light-emitting device 200, since the wiring 22 and the silicone elastomer layer 30 can be formed on the silicon substrate 210, the wirings 22 and 24 and the silicone elastomer layer 30 can be easily formed using known semiconductor manufacturing processes.

The method for manufacturing the light-emitting device 200 has the process of subjecting the surface of the silicone elastomer layer 30 to activation treatment and the process of placing the semiconductor light-emitting element 10 on the silicone elastomer layer 30. That is, according to the method for manufacturing the light-emitting device 200, the semiconductor light-emitting element 10 and the silicone elastomer layer 30 can be bonded together by activated bonding. Accordingly, it is possible, in the manufacturing process, to reduce damage applied to the semiconductor light-emitting element.

According to the method for manufacturing the light-emitting device 200, in the process of placing the semiconductor light-emitting element 10 on the silicone elastomer layer 30, the semiconductor light-emitting element 10 is placed such that the second electrode 114 of the semiconductor light-emitting element 10 and the second wiring 24 are connected via the conductive paste 42a. That is, the second electrode 114 of the semiconductor light-emitting element 10 and the second wiring 24 are connected through the connecting portion 42 including a conductive material and a resin material. With this configuration, the second electrode 114 and the second wiring 24 can be electrically connected while reducing stress generated in the semiconductor light-emitting element 10. According to the method for manufacturing the light-emitting device 200, the silicone elastomer layer 30 is formed by applying the precursor 30a of the silicone elastomer layer 30 above the silicon substrate 210 and curing the precursor 30a by heat treatment. Accordingly, since the semiconductor light-emitting element 10 can be placed on the cured silicone elastomer layer 30, it is possible to prevent the precursor 30a of the silicone elastomer layer from adhering to the light-exiting portion 11 of the semiconductor light-emitting element 10 in bonding of the semiconductor light-emitting element 10 with the silicone elastomer layer 30.

### 1.3.2. Second Modified Example

Next, a modified example of the method for manufacturing the light-emitting device 100 according to the first embodiment will be described with reference to the drawings. FIGS. 17 to 19 are cross-sectional views schematically showing the modified example of the manufacturing process of the light-emitting device 100. In FIGS. 17 to 19, the light-emitting device 100 is illustrated in a simplified manner for convenience sake.

In the method for manufacturing the light-emitting device 100 according to the first embodiment described above, the silicone elastomer layer 30 is formed above the support substrate 20 (in the example of FIG. 4, on the insulating layer 26 and on the wirings 22 and 24), and thereafter, the silicone elastomer layer 30 is bonded to the semiconductor light-emitting element 10. However, the silicone elastomer layer 30 may be formed above the semiconductor light-emitting element 10, and thereafter, the silicone elastomer layer 30 may be bonded to the support substrate 20. Hereinafter, the description will be made in detail.

As shown in FIG. 17, the silicone elastomer layer 30 is formed on the surface (on the upper surface 121 of the insulating portion 120 and the second electrode 114) of the semiconductor light-emitting element 10 on the second electrode 114 side. The silicone elastomer layer 30 is formed by applying the precursor 30a of the silicone elastomer layer 30 on the surface of the semiconductor light-emitting element 10 on the second electrode 114 side and curing the precursor 30a by heat treatment.

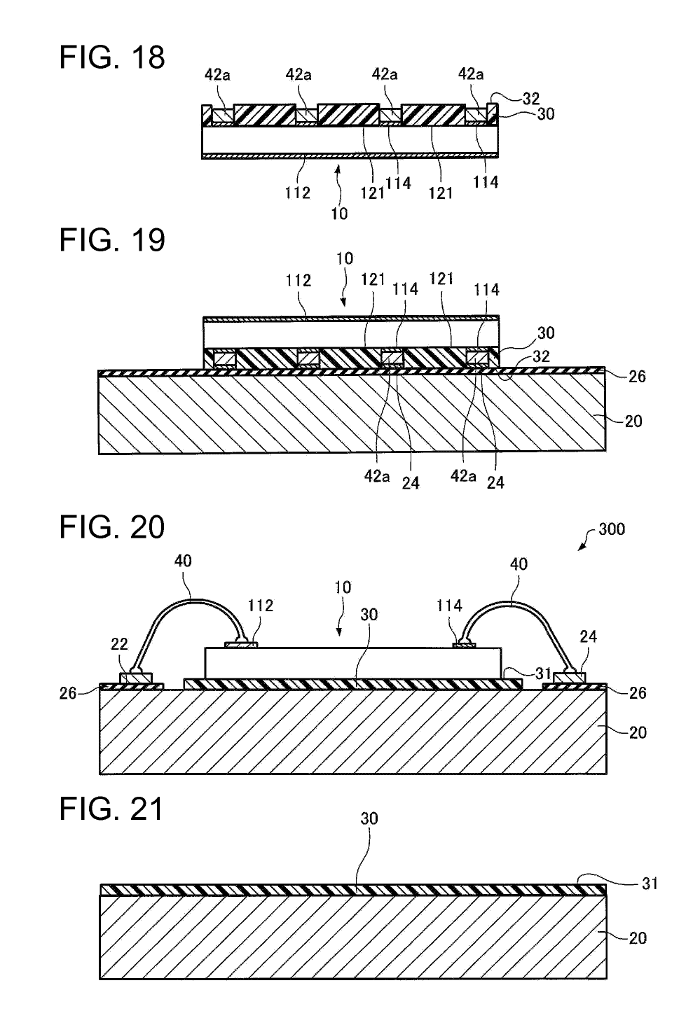

As shown in FIG. 18, the silicone elastomer layer 30 is patterned to expose the second electrodes 114 of the semiconductor light-emitting element 10. Next, a surface 32 of the silicone elastomer layer 30 is subjected to activation treatment. Next, the conductive paste 42a is arranged on the second electrodes 114.

As shown in FIG. 19, the silicone elastomer layer 30 is placed on the support substrate 20 with the surface 32 of the silicone elastomer layer 30 being directed to the support substrate 20 side. With this configuration, the silicone elastomer layer 30 and the support substrate 20 are bonded together by activated bonding. In the illustrated example, the semiconductor light-emitting element 10 is flip-chip mounted on the support substrate 20 in a junction-down state.

As shown in FIG. 1, the conductive paste 42a is cured by heat treatment to form the connecting portion 42. Next, the first wiring 22 is formed, and the first wiring 22 and the first electrode 112 of the semiconductor light-emitting element 10 are connected through the wiring wire 40.

Through the processes described above, the light-emitting device 100 can be manufactured.

According to the modified example, similarly to the method for manufacturing the light-emitting device 100 according to the first embodiment described above, it is possible, in the manufacturing process, to reduce damage applied to the semiconductor light-emitting element.

### 2. Second Embodiment

### 2.1. Configuration of Light-Emitting Device

Next, the configuration of a light-emitting device according to a second embodiment will be described with reference to the drawing. FIG. 20 is a cross-sectional view schematically showing the light-emitting device 300 according to the second embodiment. In FIG. 20, the semiconductor light-emitting element 10 is illustrated in a simplified manner for convenience sake. Hereinafter, in the light-emitting device 300, members having functions similar to those of the constituent members of the light-emitting device 100 are denoted by the same reference and numeral signs, and the detailed description thereof is omitted.

In the example of the light-emitting device 100 described above as shown in FIG. 1, the semiconductor light-emitting element 10 is mounted on the support substrate 20 in a junction-down state. In contrast to this, in the light-emitting device 300 as shown in FIG. 20, the semiconductor light-emitting element 10 is mounted on the support substrate 20 in a junction-up state. That is, the semiconductor light-emitting element 10 is mounted such that the active layer 106 is located on the opposite side of the substrate 102 of the semiconductor light-emitting element from the support substrate 20 side (in the illustrated example, the upper side).

In the light-emitting device 300, the semiconductor light-emitting element 10 has a single-sided electrode structure. In the illustrated example, the electrodes 112 and 114 are formed on the upper surface side of the semiconductor light-emitting element 10. For example, although not shown in the drawing, a single-sided electrode structure can be obtained by disposing a second contact layer (not shown) between the first cladding layer 104 and the substrate 102 shown in FIG. 3, exposing the second contact layer by dry etching or the like, and disposing the first electrode 112 on the second contact layer. As the second contact layer, an n-type GaAs layer or the like, for example, can be used.

The first wiring 22 and the second wiring 24 are disposed on the upper surface 21 of the support substrate 20 via the insulating layer 26. With the insulating layer 26, the wirings 22 and 24 can be electrically insulated from each other. The first wiring 22 is electrically connected with the first electrode 112 through, for example, the wiring wire 40. The second wiring 24 is electrically connected with the second electrode 114 of the semiconductor light-emitting element 10 through, for example, the wiring wire 40. Although, in the illustrated example, one second electrode 114 is disposed in the semiconductor light-emitting element 10, a plurality of second electrodes 114 may be disposed. Moreover, the wiring wire 40 and the second wiring 24 may be disposed for each of the plurality of second electrodes 114.

The silicone elastomer layer 30 is located between the semiconductor light-emitting element 10 and the support substrate 20. The silicone elastomer layer 30 and the semiconductor light-emitting element 10 are bonded together by activated bonding. When the semiconductor light-emitting element 10 has a single-sided electrode structure, the upper surface 31 of the silicone elastomer layer 30 and a lower surface of the substrate 102 of the semiconductor light-emitting element 10, for example, are bonded together by activated bonding.

The light-emitting device 300 has, for example, the following features.

According to the light-emitting device 300, the semiconductor light-emitting element 10 can be mounted on the support substrate 20 in a junction-up state.

The light-emitting device 300 has the silicone elastomer layer 30 located between the semiconductor light-emitting element 10 and the support substrate 20, and the semiconductor light-emitting element 10 is bonded with the silicone elastomer layer 30. Accordingly, similarly to the light-emitting device 100 described above, it is possible to reduce stress generated in the semiconductor light-emitting element due to a member bonded to the semiconductor light-emitting element.

### 2.2. Method for Manufacturing Light-Emitting Device

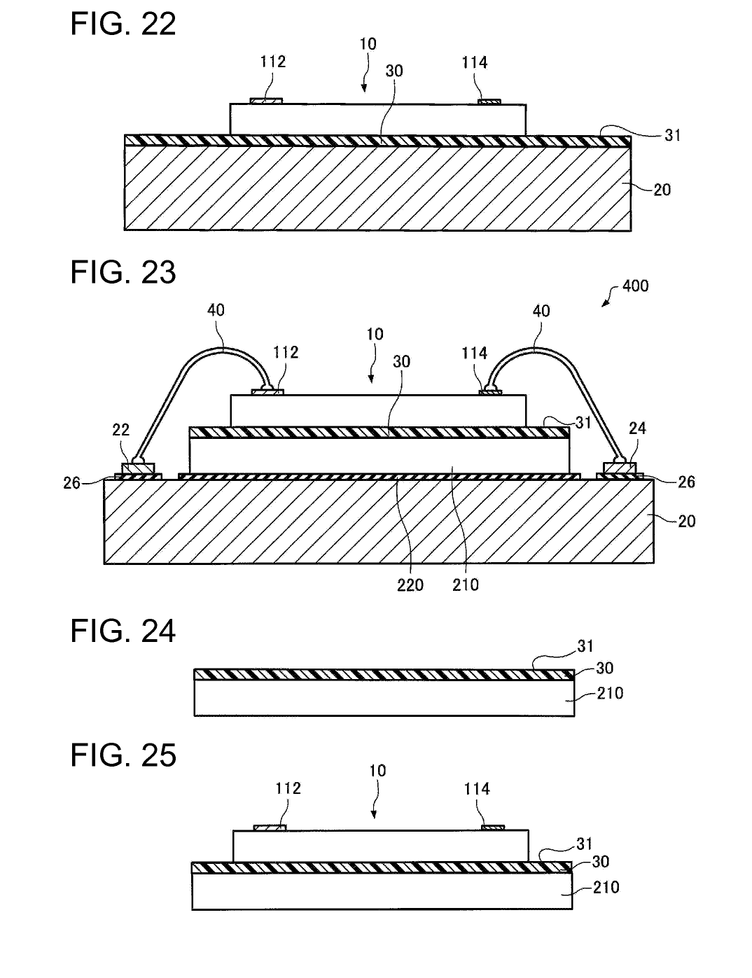

Next, a method for manufacturing the light-emitting device according to the second embodiment will be described with reference to the drawings. FIGS. 21 and 22 are cross-sectional views schematically showing the manufacturing process of the light-emitting device 300. In FIG. 22, the semiconductor light-emitting element 10 is illustrated in a simplified manner for convenience sake.

As shown in FIG. 21, the silicone elastomer layer 30 is formed on the support substrate 20. The silicone elastomer layer 30 is formed by applying the precursor 30a of the silicone elastomer layer 30 on the support substrate 20 and curing the precursor 30a by heat treatment.

Next, the upper surface 31 of the silicone elastomer layer 30 is subjected to activation treatment. In addition to the upper surface 31 of the silicone elastomer layer 30, the lower surface of the substrate 102 of the semiconductor light-emitting element 10, which is to be bonded with the upper surface 31 of the silicone elastomer layer 30, may be subjected to activation treatment.

As shown in FIG. 22, the semiconductor light-emitting element 10 is placed on the silicone elastomer layer 30. In the illustrated example, the semiconductor light-emitting element 10 is mounted in a junction-up (face-up) state. That is, the semiconductor light-emitting element 10 is mounted on the support substrate 20 with the substrate 102 side of the semiconductor light-emitting element 10 being directed to the support substrate 20 side.

As shown in FIG. 20, the wirings 22 and 24 are formed on the support substrate 20 via the insulating layer 26. Specifically, portions of the silicone elastomer layer 30 are first removed to expose the support substrate 20. Next, the insulating layer 26 and the wirings 22 and 24 are formed on the exposed support substrate 20. The wirings 22 and 24 may be previously formed on the support substrate 20. Moreover, the wirings 22 and 24 may be disposed by arranging a flexible substrate having the wirings 22 and 24 formed thereon on the support substrate 20.

Next, the first wiring 22 and the first electrode 112 of the semiconductor light-emitting element 10 are connected through the wiring wire 40. Moreover, the second wiring 24 and the second electrode 114 of the semiconductor light-emitting element 10 are connected through the wiring wire 40. The process is performed by, for example, wire bonding or the like. Through the processes described above, the light-emitting device 300 can be manufactured.

The method for manufacturing the light-emitting device 300 according to the embodiment has, for example, the following features.

According to the method for manufacturing the light-emitting device 300, the semiconductor light-emitting element 10 can be mounted on the support substrate 20 in a junction-up state. According to the method for manufacturing the light-emitting device 300, the semiconductor light-emitting element 10 and the silicone elastomer layer 30 can be bonded together by activated bonding. With this configuration, the semiconductor light-emitting element 10 and the silicone elastomer layer 30 can be bonded together at a room temperature without applying heat. Further, the semiconductor light-emitting element 10 and the silicone elastomer layer 30 can be bonded together with a low load. Accordingly, it is possible, in the manufacturing process, to reduce damage applied to the semiconductor light-emitting element. According to the method for manufacturing the light-emitting device 300, since the semiconductor light-emitting element 10 can be placed on the cured silicone elastomer layer 30, it is possible to prevent the precursor 30a of the silicone elastomer layer from adhering to the light-exiting portion 11 of the semiconductor light-emitting element 10 in bonding of the semiconductor light-emitting element 10 with the silicone elastomer layer 30.

### 2.3. Modified Example

Next, a modified example of the light-emitting device according to the second embodiment will be described with reference to the drawing. FIG. 23 is a cross-sectional view schematically showing a light-emitting device 400 according to the modified example of the second embodiment. In FIG. 23, the semiconductor light-emitting element 10 is illustrated in a simplified manner for convenience sake. Hereinafter, in the light-emitting device 400, members having functions similar to those of the constituent members of the light-emitting devices 100, 200, and 300 are denoted by the same reference and numeral signs, and the detailed description thereof is omitted.

As shown in FIG. 23, the light-emitting device 400 is configured to include, in addition to the constituent members of the light-emitting device 300, the silicon substrate 210 located between the silicone elastomer layer 30 and the support substrate 20. That is, in the light-emitting device 400, the silicon substrate 210, the silicone elastomer layer 30, and the semiconductor light-emitting element 10 are arranged in this order above the support substrate 20.

In the light-emitting device 400, the first wiring 22 and the second wiring 24 are disposed on the support substrate 20 via the insulating layer 26. The first wiring 22 and the second wiring 24 may be disposed on the silicon substrate 210. The first wiring 22 is electrically connected with the first electrode 112 of the semiconductor light-emitting element 10 through, for example, the wiring wire 40. The second wiring 24 is electrically connected with the second electrode 114 of the semiconductor light-emitting element 10 through, for example, the wiring wire 40.

In the illustrated example, the silicone elastomer layer 30 and the silicon substrate 210 are located between the semiconductor light-emitting element 10 and the support substrate 20. The silicone elastomer layer 30 and the semiconductor light-emitting element 10 are bonded together by activated bonding. When the semiconductor light-emitting element 10 has a single-sided electrode structure, the upper surface 31 of the silicone elastomer layer 30 and the lower surface of the substrate 102 of the semiconductor light-emitting element 10, for example, are bonded together by activated bonding.

The silicon substrate 210 is bonded to the support substrate 20 with the bonding member 220.

The light-emitting device 400 has, for example, the following features.

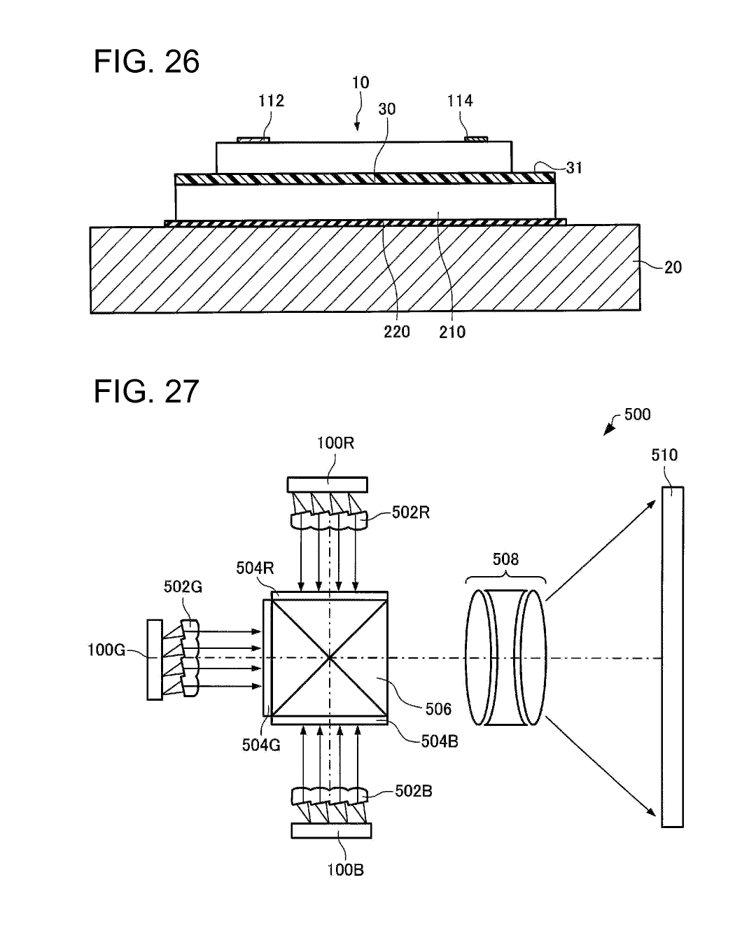

The light-emitting device 400 can have the silicon substrate 210 located between the silicone elastomer layer 30 and the support substrate 20. As described above, the difference between the thermal expansion coefficient of the silicon substrate 210 and the coefficient of thermal expansion of the semiconductor light-emitting element 10 is small compared to the difference between the thermal expansion coefficient of the support substrate 20 and the coefficient of thermal expansion of the semiconductor light-emitting element 10. Accordingly, according to the light-emitting device 400, it is possible to reduce stress generated in the semiconductor light-emitting element 10 due to the difference in the coefficient of thermal expansion between the semiconductor light-emitting element 10 and the support substrate 20. Next, a method for manufacturing the light-emitting device 400 will be described with reference to the drawings. FIGS. 24 to 26 are cross-sectional views schematically showing the manufacturing process of the light-emitting device 400. In FIG. 26, the semiconductor light-emitting element 10 is illustrated in a simplified manner for convenience sake. As shown in FIG. 24, the silicone elastomer layer 30 is formed on the silicon substrate 210. The silicone elastomer layer 30 is formed by applying the precursor 30a of the silicone elastomer layer 30 on the silicon substrate 210 and curing the precursor 30a by heat treatment.

Next, the upper surface 31 of the silicone elastomer layer 30 is subjected to activation treatment.

As shown in FIG. 25, the semiconductor light-emitting element 10 is placed on the silicone elastomer layer 30. In the illustrated example, the semiconductor light-emitting element 10 is mounted in a junction-up (face-up) state. That is, the semiconductor light-emitting element 10 is mounted on the silicon substrate 210 with the substrate 102 side of the semiconductor light-emitting element 10 being directed to the silicon substrate 210 side.

As shown in FIG. 26, the silicon substrate 210 is bonded to the support substrate 20. The silicon substrate 210 and the support substrate 20 can be bonded together using, for example, the bonding member 220 such as silver paste or heat-dissipating silicone.

As shown in FIG. 23, the wirings 22 and 24 are formed on the support substrate 20 via the insulating layer 26. The wirings 22 and 24 may be previously formed on the support substrate 20. Moreover, the wirings 22 and 24 may be disposed by arranging a flexible substrate having the wirings 22 and 24 formed thereon on the support substrate 20.

Next, the first wiring 22 and the first electrode 112 of the semiconductor light-emitting element 10 are connected through the wiring wire 40. Moreover, the second wiring 24 and the second electrode 114 of the semiconductor light-emitting element 10 are connected through the wiring wire 40. The process is performed by, for example, wire bonding or the like. Through the processes described above, the light-emitting device 400 can be manufactured.

### 3. Third Embodiment

Next, a projector according to a third embodiment will be described with reference to the drawing. FIG. 27 schematically shows the projector 500 according to the third embodiment. In FIG. 27, a housing constituting the projector 500 is omitted for convenience sake.

As shown in FIG. 27, the projector 500 includes a red light source 100R, a green light source 100G, and a blue light source 100B which emit red light, green light, and blue light, respectively. As the light source of the projector 500, the light-emitting device according to the embodiment of the invention can be used. In the following as shown in FIG. 27, an example will be described in which the light-emitting device 100 (the red light-emitting device 100R, the green light-emitting device 100G, and the blue light-emitting device 100B) is used as the light source of the projector 500. In FIG. 27, the light-emitting device 100 is illustrated in a simplified manner for convenience sake.

The projector 500 further includes lens arrays 502R, 502G, and 502B, transmissive liquid crystal light valves (light-modulating devices) 504R, 504G, and 504B, and a projection lens (projection device) 508.

Lights emitted from the light sources 100R, 100G, and 100B are incident on the respective lens arrays 502R, 502G, and 502B. The incident surface of the lens array 502 is inclined at a predetermined angle to, for example, the optical axis of light emitted from the light source 100. With this configuration, the optical axis of the light emitted from the light source 100 can be converted. Accordingly, the light emitted from the light source 100, for example, can be perpendicular to the irradiated surface of the liquid crystal light valve 504. Especially, as shown in FIG. 2, when the gain regions 160 and 170 of the semiconductor light-emitting element 10 are disposed so as to be inclined to the first side surface 131, the light emitted from the light source (the semiconductor light-emitting element 10) 100 proceeds while being inclined to the normal P of the first side surface 131. Therefore, it is desirable that the incident surface of the lens array 502 is inclined at a predetermined angle as described above. The lens array 502 can have a convex curved surface on the liquid crystal light valve 504 side. With this configuration, the light whose optical axis is converted on the incident surface of the lens array 502 is condensed by the convex curved surface, or the diffusion angle of the light can be reduced. Accordingly, the liquid crystal light valve 504 can be irradiated with good uniformity.

In this manner, the lens array 502 can control the optical axis of the light emitted from the light source 100 to condense the light.

The lights condensed by the respective lens arrays 502R, 502G, and 502B are incident on the respective liquid crystal light valves 504R, 504G, and 504B. The liquid crystal light valves 504R, 504G, and 504B each modulate the incident light according to image information.

The three colored lights modulated by the respective liquid crystal light valves 504R, 504G, and 504B are incident on a cross dichroic prism 506. The cross dichroic prism 506 is formed by, for example, bonding four rectangular prisms to each other. In the inside of the cross dichroic prism 506, a dielectric multilayer film which reflects red light and a dielectric multilayer film which reflects blue light are arranged in a cross shape. The three colored lights are combined by these dielectric multilayer films.

The light combined by the cross dichroic prism 506 is incident on the projection lens 508 as a projection optical system. The projection lens 508 magnifies an image formed by the liquid crystal light valves 504R, 504G, and 504B to project the image onto a screen (display surface) 510.

The projector 500 has the light-emitting device 100 which can reduce stress generated in the semiconductor light-emitting element due to a member bonded to the semiconductor light-emitting element. Accordingly, the projector 500 can have high reliability.

In the example described above, a transmissive liquid crystal light valve is used as a light-modulating device. However, a light valve other than liquid crystal may be used, or a reflective light valve may be used. Examples of such light valves include, for example, a reflective liquid crystal light valve and a digital micromirror device. Moreover, the configuration of the projection optical system is appropriately changed depending on the kinds of light valves to be used.

Moreover, by causing the light from the light source 100 to scan on a screen, the light source 100 can be also applied to a light source device of a scanning-type image display device (projector), such as of having scanning means, as an image forming device which displays a desired sized image on a display surface.

The embodiments and modified examples described above are illustrative only, and the invention is not limited to them. For example, it is also possible to appropriately combine each of the embodiments with each of the modified examples.

The invention includes a configuration (for example, a configuration having the same function, method, and result, or a configuration having the same advantage and effect) which is substantially the same as those described in the embodiments. Moreover, the invention includes a configuration in which a non-essential portion of the configurations described in the embodiments is replaced. Moreover, the invention includes a configuration providing the same operational effects as those described in the embodiments, or a configuration capable of achieving the same advantages. Moreover, the invention includes a configuration in which a publicly known technique is added to the configurations described in the embodiments. The entire disclosure of Japanese Patent Application No. 2011-250377, filed Nov. 16, 2011 is expressly incorporated by reference herein.

What is claimed is:

1. A light-emitting device comprising:
a semiconductor light-emitting element;
a substrate supporting the semiconductor light-emitting element; and
a silicone elastomer layer located between the semiconductor light-emitting element and the substrate, wherein
the semiconductor light-emitting element and the silicone elastomer layer are bonded together.

2. The light-emitting device according to claim 1, wherein
the semiconductor light-emitting element and the silicone elastomer layer are bonded together by activated bonding.

3. The light-emitting device according to claim 2, wherein
the semiconductor light-emitting element is mounted on the substrate in a junction-down state.

4. The light-emitting device according to claim 3, wherein
the semiconductor light-emitting element is an edge-emitting semiconductor light-emitting element.

5. The light-emitting device according to claim 2, further comprising a silicon substrate located between the silicone elastomer layer and the substrate.

6. The light-emitting device according to claim 5, wherein
the semiconductor light-emitting element is mounted on the substrate in a junction-down state.

7. The light-emitting device according to claim 3, wherein
the semiconductor light-emitting element has an electrode disposed on a surface of the semiconductor light-emitting element,
a wiring is disposed on a surface of the substrate, the surface facing the surface of the semiconductor light-emitting element, and
the electrode and the wiring are electrically connected through a connecting portion configured to include a conductive material and a resin material.

8. The light-emitting device according to claim 6, wherein
the semiconductor light-emitting element has an electrode disposed on a surface of the semiconductor light-emitting element,
a wiring is disposed on a surface of the silicon substrate, the surface facing the surface of the semiconductor light-emitting element, and
the electrode and the wiring are electrically connected through a connecting portion configured to include a conductive material and a resin material.

9. A method for manufacturing a light-emitting device, comprising:
forming a silicone elastomer layer above a substrate;
subjecting a surface of the silicone elastomer layer to activation treatment; and
placing a semiconductor light-emitting element on the silicone elastomer layer.

10. The method for manufacturing the light-emitting device according to claim 9, further comprising:
patterning, after the forming of the silicone elastomer layer, the silicone elastomer layer so as to expose a wiring disposed between the substrate and the silicone elastomer layer; and
arranging conductive paste on the exposed wiring, wherein
in the placing of the semiconductor light-emitting element on the silicone elastomer layer, the semiconductor light-emitting element is placed such that an electrode of the semiconductor light-emitting element and the wiring are connected via the conductive paste.

11. The method for manufacturing the light-emitting device according to claim 9, wherein
the forming of the silicone elastomer layer includes applying a precursor of the silicone elastomer layer above the substrate and curing the precursor by heat treatment to form the silicone elastomer layer.

12. The method for manufacturing the light-emitting device according to claim 10, wherein
the forming of the silicone elastomer layer includes applying a precursor of the silicone elastomer layer above the substrate and curing the precursor by heat treatment to form the silicone elastomer layer.

13. A method for manufacturing a light-emitting device, comprising:
forming a silicone elastomer layer above a silicon substrate;
subjecting a surface of the silicone elastomer layer to activation treatment;
placing a semiconductor light-emitting element on the silicone elastomer layer; and
bonding the silicon substrate to a substrate.

14. The method for manufacturing the light-emitting device according to claim 13, further comprising:
patterning, after the forming of the silicone elastomer layer, the silicone elastomer layer so as to expose a wiring disposed between the silicon substrate and the silicone elastomer layer; and
arranging conductive paste on the exposed wiring, wherein
in the placing of the semiconductor light-emitting element on the silicone elastomer layer, the semiconductor light-emitting element is placed such that an electrode of the semiconductor light-emitting element and the wiring are connected via the conductive paste.

15. The method for manufacturing the light-emitting device according to claim 13, wherein
the forming of the silicone elastomer layer includes applying a precursor of the silicone elastomer layer above the silicon substrate and curing the precursor by heat treatment to form the silicone elastomer layer.

16. The method for manufacturing the light-emitting device according to claim 14, wherein
the forming of the silicone elastomer layer includes applying a precursor of the silicone elastomer layer above the silicon substrate and curing the precursor by heat treatment to form the silicone elastomer layer.

17. A projector comprising:
the light-emitting device according to claim 1;
a light-modulating device modulating light emitted from the light-emitting device according to image information; and
a projection device projecting an image formed by the light-modulating device.

18. A projector comprising:
the light-emitting device according to claim 2;
a light-modulating device modulating light emitted from the light-emitting device according to image information; and
a projection device projecting an image formed by the light-modulating device.

19. A projector comprising:
the light-emitting device according to claim 3;
a light-modulating device modulating light emitted from the light-emitting device according to image information; and
a projection device projecting an image formed by the light-modulating device.

20. A projector comprising:
the light-emitting device according to claim 5;
a light-modulating device modulating light emitted from the light-emitting device according to image information; and
a projection device projecting an image formed by the light-modulating device.
